(19) United States
(12) Patent Application Publication
(10) Pub. No.: US 2010/0079079 A1
(43) Pub. Date: Apr. 1, 2010

(54) Induction lamp and fixture

(76) Inventor: Mark Hockman, Westtown, PA (US)

Correspondence Address: STITES & HARBISON PLLC, 1199 NORTH FAIRFAX STREET, SUITE 900, ALEXANDRIA, VA, 22314, US

(21) Appl. No.: 12/457,062

(22) Filed: May 29, 2009

Related U.S. Application Data
(60) Provisional application No. 61/129,043, filed on Jun. 2, 2008.

(51) Int. Cl. H05B 41/24; H01J 5/00; H05K 13/00

(52) U.S. Cl. 315/248; 313/317; 29/592.1

(57) ABSTRACT

An induction lamp includes a bulb enclosing an induction coil and having a threaded base. The threaded base is electrically connected to the induction coil without an electrically intermediate frequency generator disposed between the threaded base and the induction coil. An induction lamp fixture includes a female threaded electrical bulb socket and a frequency generator convertor unit 50-60 Hz A/C electricity to a sufficient frequency to illuminate an induction bulb. A method for retrofitting a light fixture includes connecting an output of a frequency generator having an input receiving 50-60 Hz A/C electricity, to a female threaded electrical bulb socket.

### CROSS REFERENCE TO RELATED APPLICATIONS

This application claims benefit of U.S. Provisional Patent Application No. 61/129,043, filed Jun. 2, 2008, herein incorporated by reference.

### FIELD OF THE INVENTION

The present invention relates to an induction lamp system and in particular an induction lamp with threaded end and a fixture for mounting the same.

### BACKGROUND OF THE INVENTION

Induction lamps represent a recent advancement in lighting systems which provide ultra-long life, e.g., 100,000 hours rated average life while providing high lumen output and using less energy than conventional lighting systems. Induction lamps function by passing an electrical current through a wire which creates a surrounding magnetic field. When a wire is passed through a magnetic field, an electrical current is “induced” in the wire. This transfer of energy is a principle used by electrical motors and generators. Induction lamps represent a new “green” light source that will be in great demand in the future. Typically they outlast a comparable bulb of the same wattage by ten times.

Induction lamps have no filament and are very efficient lasting ten times as long as a normal high and low pressure sodium and metal hailiad bulbs. Current manufacturers include General Electric, Phillips, and Sylvania. A typical induction lamp system comprises an induction lamp or bulb, a power supply unit, also known as a frequency generator, which supplies a high-frequency alternating current, and a power supply cable connecting the frequency generator to the induction lamp. The lamp comprises an induction coil surrounded by an electron/ion plasma or gas environment within a phosphor coated bulb. The bulb is mounted in a heat sink base. Wires from the frequency generator enter the base of the bulb to provide high frequency alternating current to illuminate the induction bulb.

The original induction lamps locate the frequency generator away from the induction bulb, with wires running from the frequency generator to the base of the bulb. The frequency generator generates an electric alternating current at the requisite frequency that radiates from a rod inside the hollow induction bulb which excites gases in the bulb to create light. The frequency is significantly higher than standard 50 Hz or 60 Hz AC current. For example, the frequency may be around 2.0 MHz to 260 kHz.

Referring to FIG. 7, one prior art induction lamp system manufactured by Shenzhen Green Light Electronics Technology Co., Ltd. comprises induction bulb 121 mounted in ceramic base 122. A pair of wires hardwire the induction bulb 121 to a frequency generator 140. The frequency generator 140 is connected to a standard 50-60 Hz A/C power source via wires 143. The frequency generator 140 produces the requisite high frequency A/C to illuminate bulb 121.

One recent modification of induction bulbs was to modify the original induction bulb by adding a conventional threaded male end so that the induction bulb could fit in a conventional socket. Since induction bulbs require a specific high frequency current rather than standard AC, the threaded end of the bulb also included a frequency generator and all other electronics to power the bulb. A manufacturer of such an integrated induction bulb is General Electric which sells its product under the name GENURA Self-Ballasted Electrodeless Induction Lamp.

One disadvantage of integrating electronics within an induction lamp is that this increases the diameter of the bulb and/or its length in order to accommodate all electronics within the lamp housing. As a result, the added size may make the integrated induction bulb not suitable to fit in conventional lighting fixtures. In addition, having the electronics so close to the induction bulb will cause heat to build up in the electronics in the threaded end and may cause damage to the electronics in the threaded end of the bulb.

### SUMMARY OF THE INVENTION

The present invention is directed to several aspects of an induction bulb system. In one form, the present invention is directed to an induction lamp which has a threaded end dimensioned to fit in a convention light bulb socket of current industrial fixtures.

The present invention, in another form, is directed to an induction light fixture, itself, which is designed to accommodate the present induction lamp. The present fixture may be formed by retrofitting an existing fixture or the present fixture can be manufactured as a new fixture. With regard to the retrofitted fixture, an existing fixture can be modified to accept the present induction lamp by modifying the electrical current supplied to a conventional industrial bulb socket in order to illuminate the present induction bulb.

In both the retrofitted fixture and a new fixture, a frequency generator is located within the housing of the light fixture, but away from the location of the bulb. In the retrofitted fixture, the conventional socket is modified by removing the standard alternating current wires which run directly to the socket and replacing them with wires which connect the socket to the frequency generator. The present induction bulb with threaded end can be screwed into the modified conventional female socket and the frequency generator can generate current at the requisite frequency to illuminate the present lamp.

### BRIEF DESCRIPTION OF THE FIGURES

FIG. 1 is a perspective view of an induction lamp system in accordance with the present invention;

FIG. 2 is a perspective view of a portion of the induction lamp of FIG. 1, with the induction lamp removed from the bulb socket;

FIG. 3 is a perspective view of the induction lamp with the cover over the lamp housing;

FIG. 4a is a perspective view of a frequency generator in accordance with the present invention;

FIG. 4b is a perspective view of the induction lamp;

FIG. 5a is a perspective view of the induction lamp system with the lamp inserted into the socket;

FIG. 5b is a perspective view of the induction lamp system with the lamp not inserted into the socket;

FIG. 6 is a perspective view of the induction lamp system with lamp illuminated; and

FIG. 7 is a perspective view of a prior art induction lamp system.

### DETAILED DESCRIPTION OF THE PREFERRED EMBODIMENTS

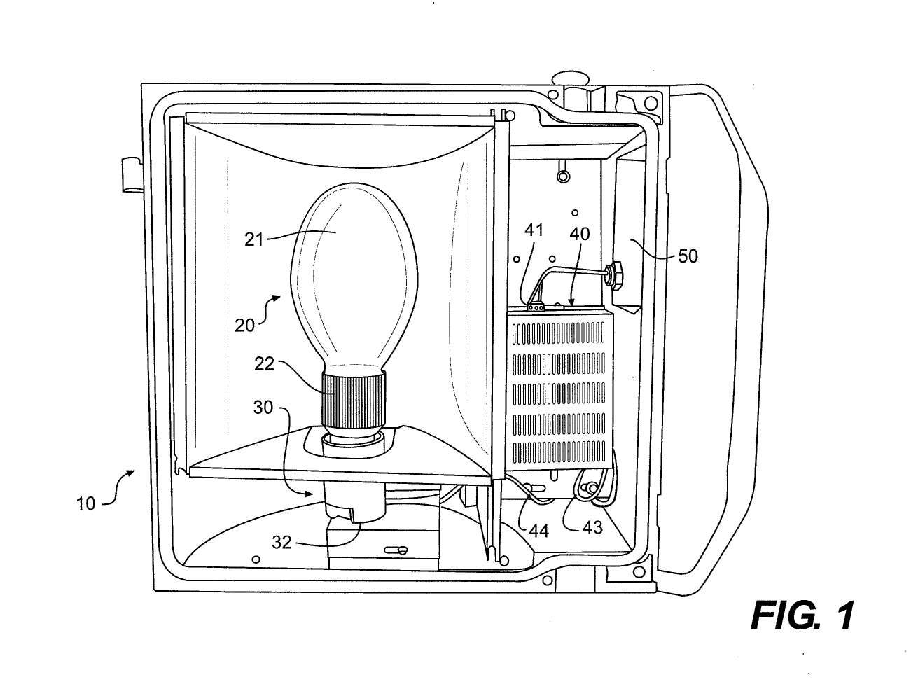

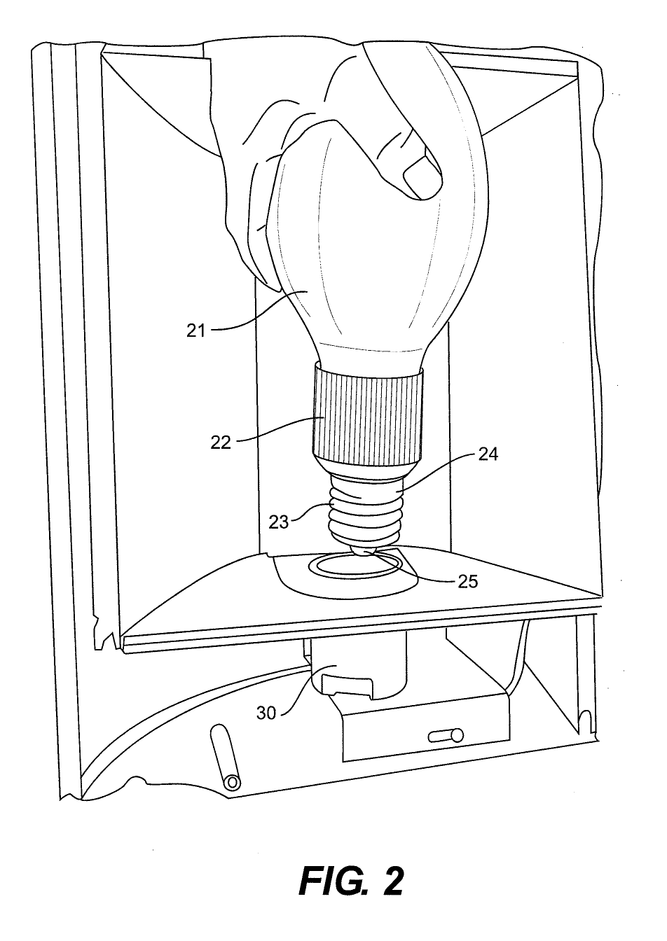

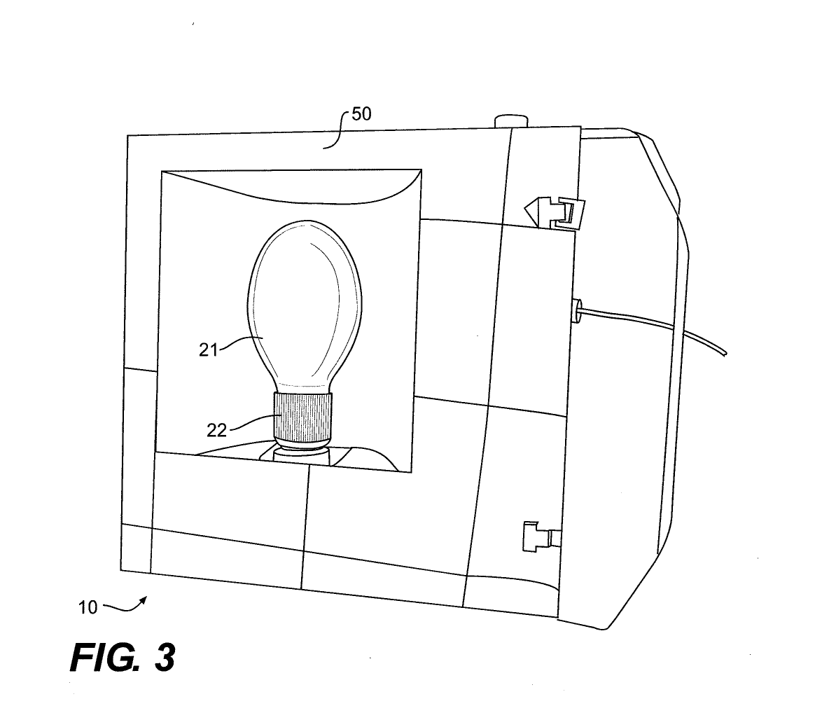

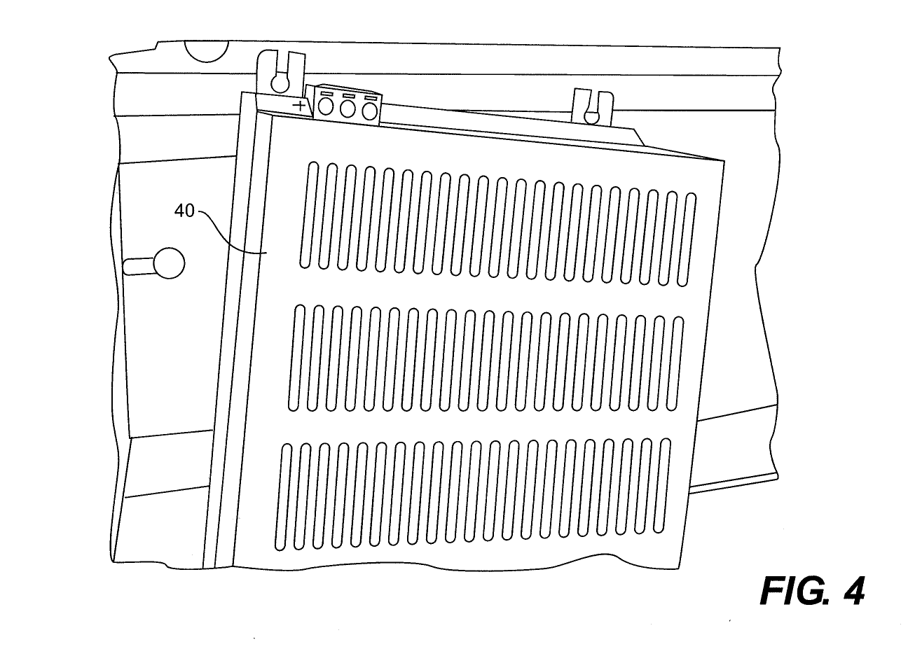

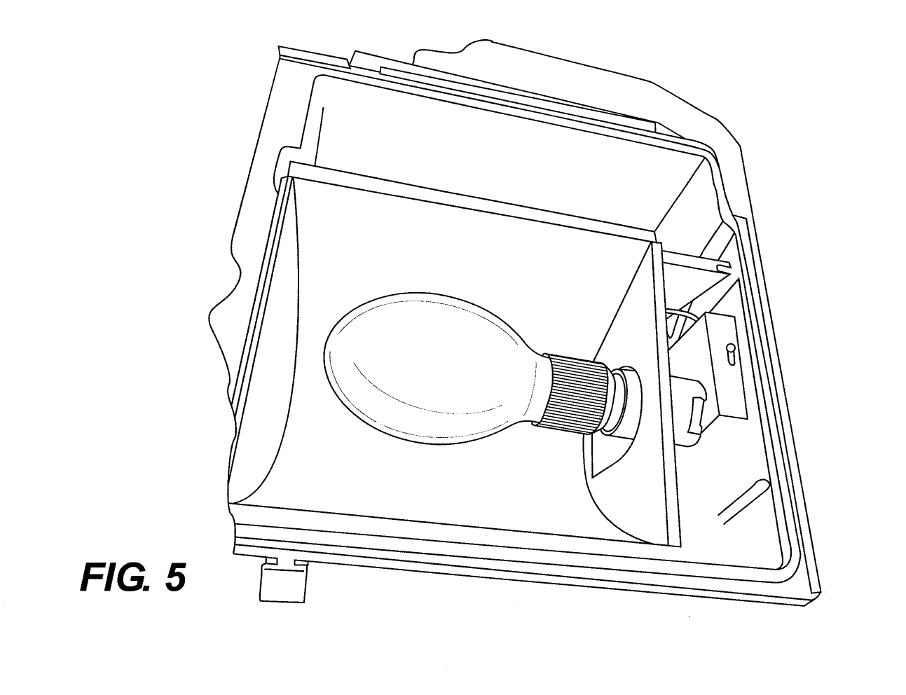

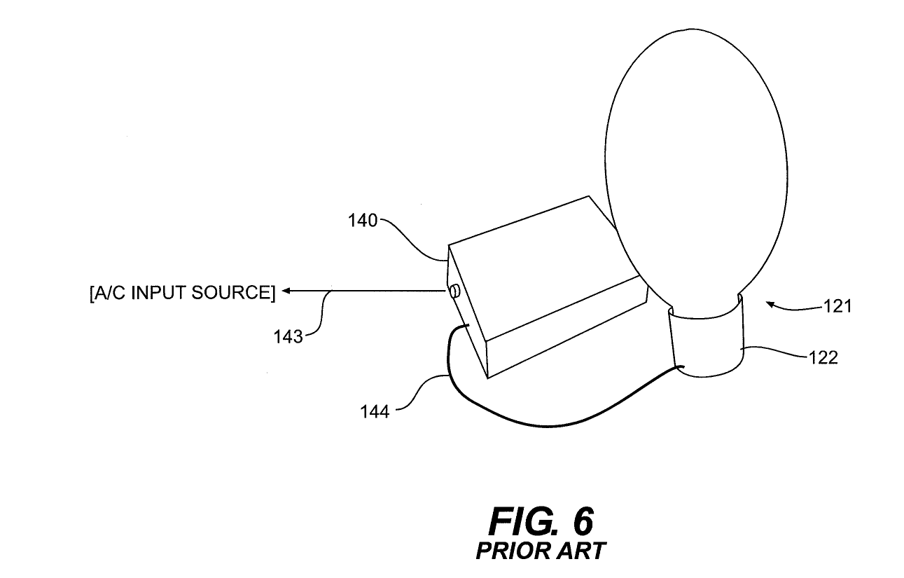

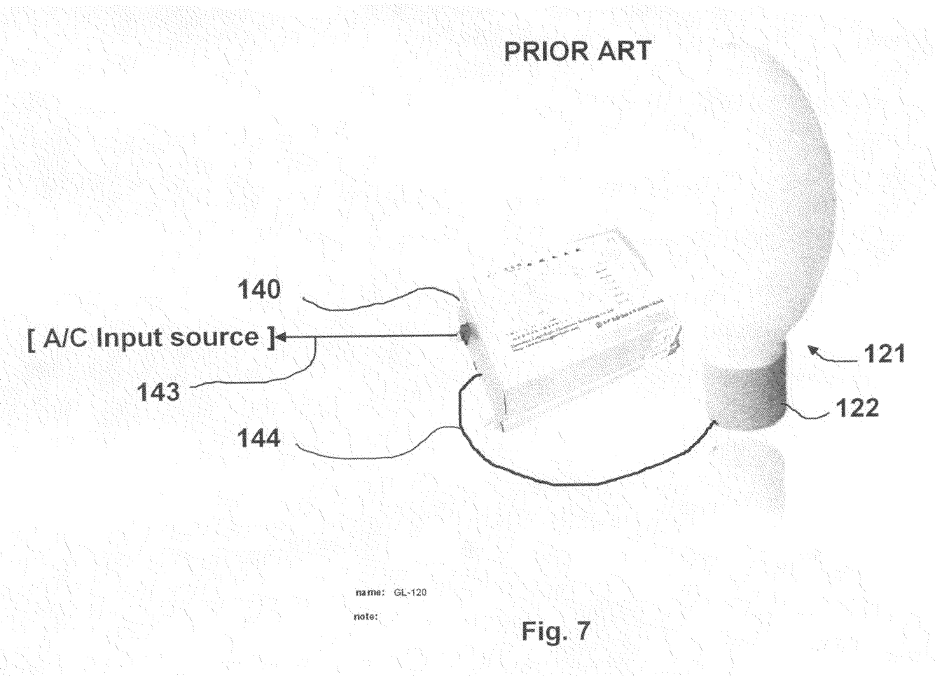

Referring now to the figures, FIGS. 1 and 2 depict the present induction system 10. Induction system 10 comprises induction lamp 20, socket 30, frequency generator 40, and housing 50. Induction lamp 20 comprises a conventional induction bulb 21 having a heat sink ceramic base 22 and male threaded end 23. The threaded end 23 is disposed at the base of the heat sink 22. The dimensions of threaded end 23 are the same as a conventional industrial light bulb. Threads 24 and the bottom 25 are connected to the terminals of induction bulb 21. Other than wires running from the threads 24 and bottom 25 to the respective terminals of bulb 21, threaded end 23 does not contain any other electronics.

Female socket 30, as previously noted, is a conventional socket for receiving industrial bulbs. Accordingly, two wires enter socket 30 for providing high frequency AC to the threads 24 and bottom 25.

Frequency generator 40 has a pair of input terminals 41 for receiving alternating current, e.g., at 50 or 60 Hz, from a power source (not shown). A pair of output terminals 43 provides the requisite frequency current through wires 44 to the terminals in socket 30. The frequency may be between 2.0 MHz and 260 kHz depending on the requirements of bulb 21. Alternating current is delivered to frequency generator 40 at the requisite frequency to bulb 21 through socket 30.

One advantage of the present induction lamp system is that it allows for easy retrofitting of existing industrial lamp installations. In order to implement the present system one needs only to remove the existing alternating current wire inputs to socket 30, insert a frequency generator 40 within the existing light fixtures housing, and connect wires 44 to the existing alternating current terminal of a conventional lamp socket. Then one can easily unscrew a conventional bulb and insert a new lamp 20 into the modified conventional socket 30.

An additional advantage of the present induction bulb system is that unlike other prior integrated induction lamps which integrate the frequency generator in a threaded base of the induction bulb, the present threaded end 23 does not include the frequency generator therein. Instead, the frequency generator is located remote and spaced away from bulb 21 yet inside housing 50. As shown in FIG. 1, the frequency generator 40 is actually located in a separate compartment away from the bulb 21. Accordingly, the frequency generator 40 is not susceptible to heat generated by lamp 20 which would occur were the frequency generator 40 located in the threaded end 23.

As previously noted, an induction lighting fixture which comprises socket 30, frequency generator 40, and housing 50, can either be manufactured as a new fixture or an existing light fixture can be modified by including the frequency generator 40 within an existing light fixture and re-wire the fixture to connect the frequency generator to the existing light bulb socket.

Although the invention has been described above in relation to preferred embodiments thereof, it will be understood by those skilled in the art that variations and modifications can be effected in these preferred embodiments without departing from the scope and spirit of the invention.

1. An induction lamp comprising:
a bulb enclosing an induction coil and having a treaded base, the threaded base electrically connected to the induction coil without an electrically intermediate frequency generator disposed between the threaded base on the induction coil.

2. An induction lamp fixture comprising:
a female threaded electrical bulb socket; and
a frequency generator converting 50-60 Hz A/C electricity to a sufficient frequency to illuminate an induction bulb, said frequency generator electrically connected to the threaded electrical bulb socket.

3. An induction lamp system comprising:
a female threaded electrical bulb socket;
a frequency generator converting 50-60 Hz NC electricity to a sufficient frequency to illuminate an induction bulb, said frequency generator electrically connected to the threaded electrical bulb socket; and
a bulb enclosing an induction coil and having a treaded base, the threaded base electrically connected to the induction coil without an electrically intermediate frequency generator disposed between the threaded base on the induction coil, said bulb threaded base threadingly engageable in the female threaded electrical bulb socket.

4. A method for retrofitting a light fixture, said method comprising:
providing a light fixture comprising a female threaded electrical bulb socket having an electrically input for being connected to a 50-60 Hz NC power source;
providing a frequency generator having an input receiving 50-60 Hz NC electricity and an output for proving a sufficient frequency to illuminate an induction bulb; and
connecting the output of the frequency generator to the electrical input of the female threaded electrical bulb socket.
